(19) United States
(12) Patent Application Publication
(10) Pub. No.: US 2008/0072112 A1
(43) Pub. Date: Mar. 20, 2008

(54) Sequential Scan Technique Providing Reliable Testing of an Integrated Circuit

(75) Inventors: Devanathan Varadarajan, Chennai (IN); Ravikumar P. Chennagiri, Bangalore (IN)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/567,751

(22) Filed: Dec. 7, 2006

(30) Foreign Application Priority Data
Sep. 14, 2006 (IN) 1685/CHE/2006

(51) Int. Cl. G01R 31/28

(52) U.S. Cl. 714/738

(57) ABSTRACT

Determining a scan vector which would test an integrated circuit (IC) while ensuring counts in respective portions of the IC would not exceed corresponding thresholds. In an embodiment, the threshold represents a number of toggles in the corresponding portion. The toggles can include the transitions that would be caused by the logical operation of the combinatorial elements in the IC as well as the transient glitches caused by arrival of input signals at different time points.

### RELATED APPLICATION(S)

The present application is related to and claims priority from the co-pending India provisional application serial number 1685/CHE/2006, entitled, “Power Profiling and Pattern Generation for Power_Safe Scan Tests”, filed on: Sep. 14, 2006, attorney docket number TXN_{—}169/TI_{—}63333, naming the same inventors as in the present application as the inventors, and is incorporated in its entirety herewith.

### BACKGROUND OF THE INVENTION

1. Field of the Invention

The present invention relates generally to the field of testing of integrated circuits, and more specifically to a sequential scan technique providing reliable testing of an integrated circuit.

2. Related Art

Sequential scan techniques are often used to test integrated circuits. According to one sequential scan technique, testing of the integrated circuit (IC) is performed in two phases, a shift phase and a capture phase, which are both described below in detail.

In a shift phase various memory elements (contained in the integrated circuit) such as flip-flops are connected in a sequence referred to as a “scan chain” (i.e., the output of one element is connected as an input to the next element). A scan vector (test pattern) containing a number of bits in a particular pattern of zeros and ones is sequentially loaded (scanned in) into the scan chain through the first element in the scan chain.

Capture phase is performed after scan chain is loaded with an input scan vector. In capture phase, the integrated circuit is connected according to a desired design/topology (to provide the utility for which the IC is designed in normal mode of operation) and a desired number of clock pulses (one or more) are applied. In the capture phase, the elements (generally the combinatorial logic) in the integrated circuit are evaluated based on the scanned in bits (scan vector). The flip-flops are designed to latch the results of the evaluation.

The bits latched in the scan chain may be sequentially unloaded (scanned out) one bit at every clock cycle through the last element in the scan chain. Often the loading of scan vector and unloading of results (output scan vector) are performed in parallel (shift phase). For example, while a new scan vector is loaded, the result from the previous evaluation is unloaded. The received scan out is compared with the expected scan out corresponding to the scan vector to determine the various faults within the integrated circuit.

Each pattern is generated to determine a desired set of faults such as stuck at faults and timing fault at desired nodes. In general, it is desirable to generate the patterns such that the faults will be detected accurately under various operating conditions.

### BRIEF DESCRIPTION OF THE DRAWINGS

The present invention will be described with reference to the following accompanying drawings, which are described briefly below.

FIG. 1 is a block diagram illustrating the details of an example environment in which various aspects of the present invention is implemented.

FIG. 2 is a block diagram of an integrated circuit illustrating some general principles according to which test patterns are generated in an embodiment.

FIG. 3 is a flowchart illustrating a test pattern generation technique provided for reliable testing of an integrated circuit according to an embodiment of the present invention.

FIG. 4A is an example power grid structure of an integrated circuit illustrating portions associated with which thresholds are specified in one embodiment.

FIG. 4B depicts the threshold value allocation representing the permissible number of toggles in different portions of an integrated circuit (IC).

FIG. 4C depicts the location of different combinatorial elements (gates) in different portions of an IC.

FIG. 5 is a circuit diagram illustrating example reasons/sources of glitches, which cause additional power dissipation.

FIG. 6A is a timing diagram illustrating absence of glitches assuming an ideal zero delay model.

FIG. 6B is a timing diagram illustrating a glitch caused due to a non-zero delay model in the case of a static glitch (i.e., output not expected to change).

FIG. 6C is a timing diagram illustrating a glitch caused due to a non-zero delay model in the case of a dynamic glitch (i.e., output expected to change).

FIG. 6D is an example table depicting the magnitude of the glitches considering a non-zero delay at the output of an AND gate for each combination characteristics of input signals.

FIG. 7 is a flowchart illustrating the manner in which an input scan vector can be determined for testing a fault location according to an aspect of present invention

FIG. 8 is a flowchart illustrating the determination of paths according to an aspect of present invention.

FIG. 9A is a circuit diagram illustrating path selection according to an aspect of present invention.

FIG. 9B is a table depicting signal arrival and departure time of relevant/some gates in FIG. 9A.

FIG. 10 is a flowchart illustrating the manner in which an optimized set of input scan vectors may be generated from a initial pattern set according to an aspect of the present invention.

FIG. 11 is a block diagram of a digital processing system illustrating an example system in which various aspects of the present invention can be implemented.

In the drawings, like reference numbers generally indicate identical, functionally similar, and/or structurally similar elements. The drawing in which an element first appears is indicated by the leftmost digit(s) in the corresponding reference number.

### DETAILED DESCRIPTION

### 1. Overview

An aspect of the present invention enables thresholds to be specified with different physical/layout portions of an integrated circuit, and a test vector is generated to ensure that the thresholds are not exceeded when the integrated circuit is tested with the test vector. Additional thresholds may be specified associated with the overall integrated circuit. As a result, the test vectors may be generated such that the operation of the overall chip as well as the individual portions is within desired parameters.

In one embodiment, each threshold represents a number of toggles permitted in the corresponding portion. As the power dissipation is generally proportionate to toggles, portions having higher tolerance to power dissipation may be specified with higher threshold values.

According to another aspect of the present invention, the circuit is analyzed for glitches (representing transitions in transient state caused due to different arrival times of input signals to combinatorial elements), and the glitches are also considered in generating the scan vectors. In an embodiment, the glitches is considered along with the transitions (which would be caused by logical operation of the combinatorial elements in steady state) as being toggles.

According to one more aspect of the present invention, a (part of the) scan vector is determined by first selecting an intermediate node sought to be tested, and selecting a path from the intermediate node to the output terminal of a sequential element (i.e., primary input) based on at least one of physical (e.g., location, size, characteristics defined by fabrication technology) and timing (propagation delay introduced, expected time instance at which signals are expected to be received, etc.) characteristics of the components (e.g., combinatorial element and signal paths connecting the combinatorial elements).

In one embodiment, the inherent delays in the individual gates driving the input nodes of the combinatorial element driving the intermediate node, expected time of arrival of the input signals to corresponding at the individual gates and the physical location of the gates are considered in that order in determining the path to the primary inputs from the intermediate node.

According to yet another aspect of the present invention, an initial set of scan vectors are examined for violations of the thresholds specified with corresponding portions of an IC, and a set of violating vectors causing the violations are determined. The set of intermediate nodes tested by the violating vectors are determined and replacement vectors testing the same intermediate nodes are computed. The computed set of replacement vectors are then added in place of the violating vectors to generate a new set of acceptable scan vectors t test the IC.

Several aspects of the invention are described below with reference to examples for illustration. It should be understood that numerous specific details, relationships, and methods are set forth to provide a full understanding of the invention. One skilled in the relevant art, however, will readily recognize that the invention can be practiced without one or more of the specific details, or with other methods, etc. In other instances, well known structures or operations are not shown in detail to avoid obscuring the features of the invention.

### 2. Example Environment

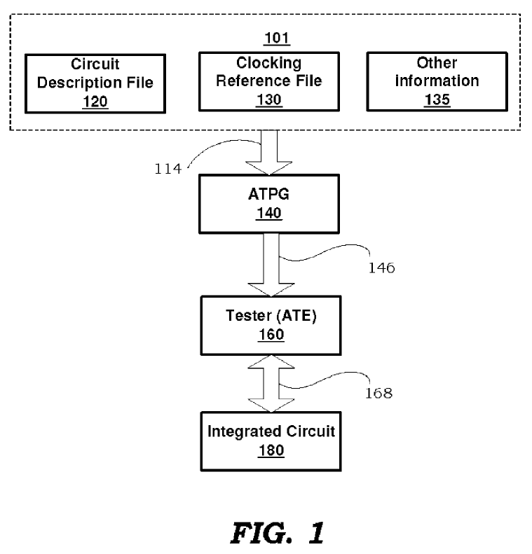

FIG. 1 is a block diagram illustrating the details of an example environment in which various aspects of the present invention is implemented. The environment is shown containing circuit description file 120, clocking reference file 130, other information 135, ATPG (Automatic test pattern generator) 140, tester (ATE) 160 and integrated circuit 180. Each block is described in further detail below.

Integrated circuit 180 is designed to operate in a functional mode and a test mode, explained briefly above. Integrated circuit 180 provides interface 168 for enabling sequential scan test. Interface 168 may contain scan-in terminals, scan-out terminals, clock signal, scan enable terminals/signals and other data terminals.

Scan-in terminals provide the interface for loading a scan chain and scan-out terminal provides interface for unloading the result of an evaluation. In general, each of the number of scan-in terminals and number of scan-out terminals equals the number of scan chains used for testing the integrated circuit 180.

Tester (Automatic test equipment) 160 receives test patterns from ATPG 140. In one embodiment, the test patterns include scan vectors, data representing timing of clock pulses, reference time for switching scan enable signal from one logic level to other, logical levels on other data terminals and expected result for each scan vector loaded.

Tester 160 generates test signals according to the test patterns. The test signal containing the clock signal, scan enable signal and pulses representing scan vectors are provided to integrated circuit 180 on corresponding terminals of interface 168. Tester 160 receives the result of the evaluation on scan-out terminal and compares the received result with the expected result. Tester 160 may also hold other data terminals at a desired logic levels as specified in the test pattern.

Circuit description file 120 provides the details of elements/component and connectivity within integrated circuit 180, for example, in the form of Netlists, well known in the relevant arts. Clocking reference file 130 may provide details of operational frequency of each component, timing for clock signal for performing the test, time reference for switching scan enable signal, etc. Other information 135, provided according to an aspect of the present invention, contains timing information of various signals to the combinational logic elements, power grid information, switching information etc., and is used for generating scan vectors as described in sections below.

ATPG 140 provided according to various aspects of the present invention, generates test patterns to detect desired faults within integrated circuit 180. The various features of the present invention will be clearer in comparison to a prior approach in which at least some features of the present invention are not implemented. Accordingly, the details of such a prior system generating test patterns are described below first with respect to an example integrated circuit.

### 3. General Principles

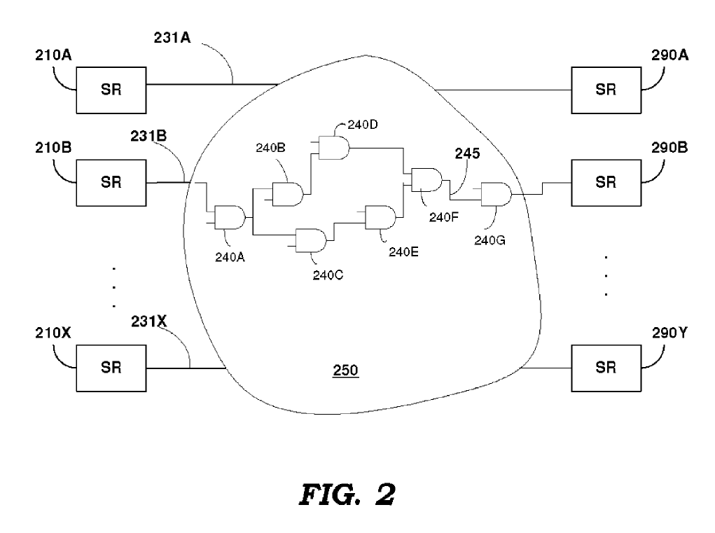

FIG. 2 is a block diagram of an integrated circuit illustrating some general principles according to which test patterns are generated in an embodiment. The integrated circuit is shown (logically) containing sequential elements 210A-210X and 290A-290Y and combinational logic 250. Each component is described in further detail below.

The output terminals of sequential elements 210A-210X are shown connected to input terminals (primary input terminals) 231A-231X of the combinational logic 250 (representing the connection in capture phase). An example portion of the combinational logic circuit is shown containing AND gates 240A-240G (merely for ease of understanding).

In a scan mode, prior to capture phase, sequential elements 210A-210X may be connected as a scan chain (not shown) to scan in the desired input scan vector. The outputs resulting from the capture phase are captured into sequential elements 290A-290Y, which may again be connected as a scan chain (not shown) and the captured values may be scanned out as an output scan vector for comparison with the expected result. Though shown as different sequential elements, it would be readily apparent to one skilled in the relevant arts that there would be common sequential elements in the input and output scan chains.

To generate the input scan vectors, according to one approach, a fault node (say 245) is selected first, and paths respectively connecting each primary input terminal 231A-231X to fault node 245 are selected. Logic values on each of the input terminals 231A-231X is computed to excite or set a known transition or value on fault node or path (generally “location”). The computed logic values on the primary input terminals 231A-231X represents an input scan vector. The desired transitions can be obtained by having multiple clock cycles/transitions in a evaluation phase or by multiple scan vectors in different evaluation phases.

It may be appreciated that, there exist multiple paths (to set a desired logical value on the desired node) between a desired node (fault node) 245 to each of primary input terminals 231A-231X. For example, AND gates 240A, 240B, 240D, and 240F form a first path between fault node 245 and primary input terminal 231B and AND gates 240A, 240C, 240E, and 240F form a second path between fault node 245 and primary input terminal 231B Accordingly, a large number of (exponential) such paths exist between the set of nodes and input terminals 231A-231X for selection.

In one prior embodiment, paths from fault node to primary inputs are randomly selected from large number of possible paths between fault node 245 and each primary input terminals 231A-231X. In another prior embodiment, controllability are taken into consideration while selecting paths towards primary inputs. Controllability refers to ability to set a node to a desired value. For example, if a node is desired to be set to a 0, an AND gate driving the node would be a better choice since 0 can be more easily obtained (since only one input has to be controlled) compared to an OR gate. Such an approach is described in further detail in a document entitled, “ATPG for Heat Dissipation Minimization During Test Application”, by S. Wang, S. K. Gupta, IEEE Transactions on Computers, February 1998.

Often, such selection is performed by using back trace (For example, Path oriented decision making in D_algorithm, PODEM) technique as well known in the relevant arts and described in a document entitled, “An Implicit Enumeration Algorithm to Generate Tests for Combinational Logic Circuits”, by P Goel, IEEE Transactions on Computers, March 1981. Specific vectors thus computed may be determined to be suitable input scan vectors so long as the vectors do not violate some thresholds set for the entire IC (total power dissipated by the entire IC) being tested.

However, applying scan vectors computed according to such a technique may cause large power dissipation (particularly due to transitions in various paths) while performing sequential scan tests. Such power dissipation often results in IR drop. As a result, various gates in the path may receive a signal with a lesser strengths (low voltage level insufficient to drive the logic gate), thereby resulting in undesired test results. Further such IR drop may increase the gate delay resulting in failure of timing related tests (at-speed tests). The IR drop is of particular concern in case of wire-bond package/die based ICs.

The manner in which various aspects of present invention overcome at least some of the disadvantages noted above is illustrated below in further detail.

### 4. Generating Test Patterns

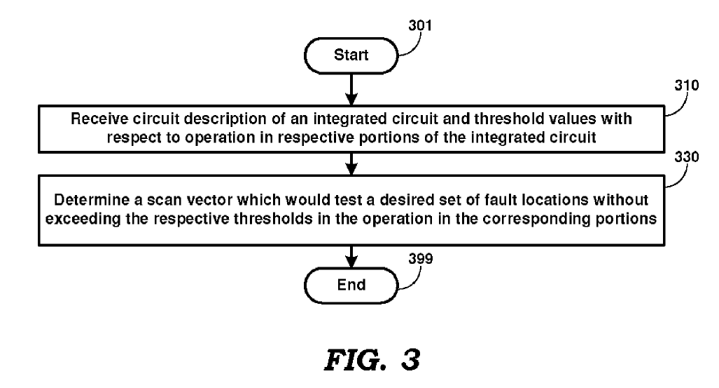

FIG. 3 is a flowchart illustrating a test pattern generation technique provided for reliable testing of an integrated circuit according to an embodiment of the present invention. The flowchart is illustrated with reference to FIG. 1 merely for illustration. However, the features can be implemented in various other test environments, as will be apparent to one skilled in the relevant arts by reading the disclosure provided herein. The flowchart begins in step 301 and control passes to step 310.

In step 310, ATPG 140 receives the circuit description of an integrated circuit and threshold values with respect to operation in respective portions of the integrated circuit. Though the description in sections below is provided substantially with respect to a maximum number of transitions (toggles) in a portion of the IC, the features can be extended to other operational aspects such as a maximum number of gates/nodes, path length, etc., in a signal transition path within each portion, as will be apparent to one skilled in the relevant arts by reading the disclosure provided herein.

In step 330, ATPG 140 determines a scan vector which would test a desired set of fault locations without exceeding the respective thresholds in the operation in the corresponding portions. Any approach can be used to determine the scan vectors while ensuring that the later testing would not violate the respective thresholds in the corresponding portions of the IC. The flow chart ends in step 399.

Tester 160 then uses such determined scan vectors to test the integrated circuit. Due to the thresholds for separate portions of the IC, various undesired characteristics (e.g., excessive power dissipation) can be avoided even within smaller portions of the IC.

The description is continued in an example scenario with each portion corresponding to a rectangular logical area containing multiple power grids, and a threshold is set to a total number of transitions in each area (for example, to avoid excessive power dissipation locally) of the combinatorial logic during the capture phase.

### 5. Example

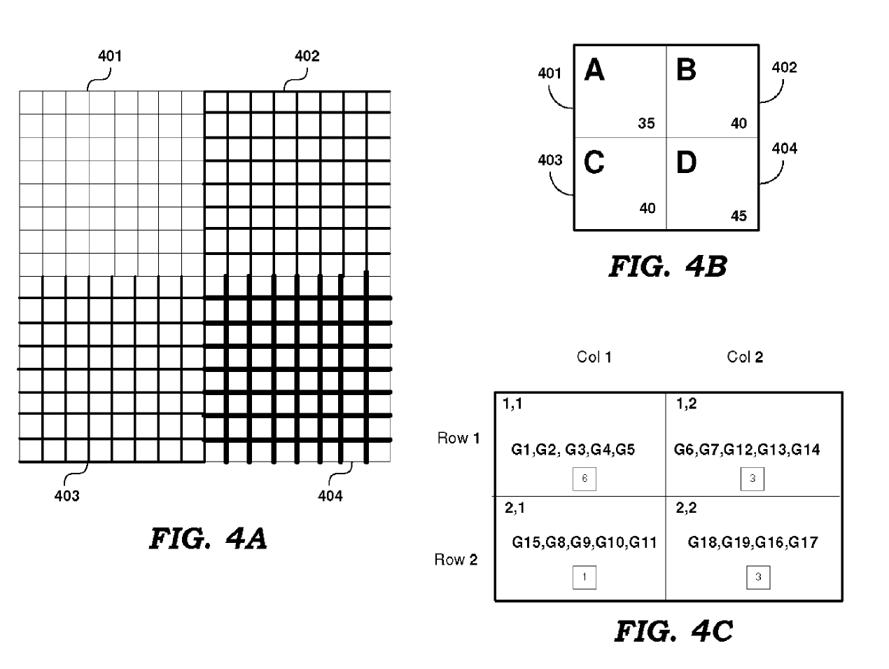

FIG. 4A is an example power grid structure of an integrated circuit illustrating portions associated with which thresholds are specified in one embodiment. The grid structure is shown containing portions 401-404, each having different power dissipation tolerance, as described below in further detail.

Portion 401 is shown with thin power straps, portions 402 and 403 are shown with normal (or medium) sized power straps, and portion 404 is shown with thick power straps. Such variations in the thickness of the power straps (the power grid topology) in the integrated circuit may be based on the functional (i.e., normal or non-test mode of operation) power consumption pattern of corresponding portions of the integrated circuit.

Due to such different sized power straps, it is assumed that portion 401 supports (or tolerant to) a localized low power dissipation/consumption, portions 402 and 403 support a moderate power consumption, and portion 404 support a maximum power consumption. As well known in the field of art, a logic gate switching from one logic state to other (toggle) often contributes to the power dissipation.

Accordingly, the number of toggles (in capture phase) in each portion 401-404 contributes to the power dissipation in the corresponding portion. Thus, power dissipation/consumption limit in each portion 401-404 may be represented in terms of maximum allowable number of toggles, as depicted in FIG. 4B.

Continuing with reference to FIG. 4B, portion 401 is shown as supporting 35 toggles, portions 402 and 403 as supporting 40 toggles respectively, and portion 404 as supporting 45 toggles.

Thus, for irregular power grid design depicted in FIG. 4A, the maximum allowable number of toggles may be represented as threshold values. The threshold values may be specified as 35, 40, 40, 45 respectively for portions 401, 402, 403 and 404. The manner in which number of toggles in the capture phase may be restrained to the thresholds according to various aspects of the present invention is described below in further detail.

In one embodiment, the gates (in combinatorial logic 250) are assigned to different portions 401-404 based on the physical location in the die (on which the IC is fabricated). The location/layout information may be available from the output of placement/routing tools used in the design of the integrated circuit. The corresponding assignment may be stored as an array, as described below with respect to FIG. 4C.

FIG. 4C is a example array depicting the portions to which various circuit elements (gates) are assigned based on the physical locations of the gates. Each portion A, B, C and D in the array are respectively allocated with coordinates (1,1), (1,2), (2,1) and (2,2). The allocation may be performed based on its physical location on the die. Gates G1,G2, G3,G4 and G5 are shown assigned to portion A, gates G6,G7,G12,G13 and G14 are shown assigned to portion B, gates G15,G8,G9,G10, and G11 are shown assigned to portion C, and gates G18,G19,G16, and G17 are shown assigned to portion D.

The number of transitions may be computed based on the expected responses to the input vector according to the topology (connectivity) and the type (AND gate, OR gate, etc.) of elements in the combinatorial logic. Thus, the inputs for each of the gates may be examined to determine if a transition would occur at the corresponding output terminal. The scan vector may be determined to be unsuitable if the computed number of transitions in any portion exceeds the corresponding threshold.

Such local thresholds may be used in conjunction with constraints for global (i.e., for the entire IC). Constraints for global and local toggle counts may ensure that for any source scan vector, the total number of toggles for all regions is lesser than the global toggle count constraint, and number of toggles within each region is lesser than the local toggle constraint. The global toggle constraint ensures that the global peak power is within the limits, while the local toggle constraint ensures that high localized switching activity, that could potentially lead to IR_drop failure, is within acceptable limits.

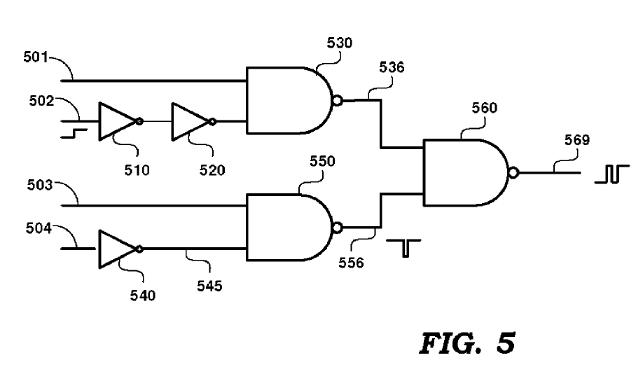

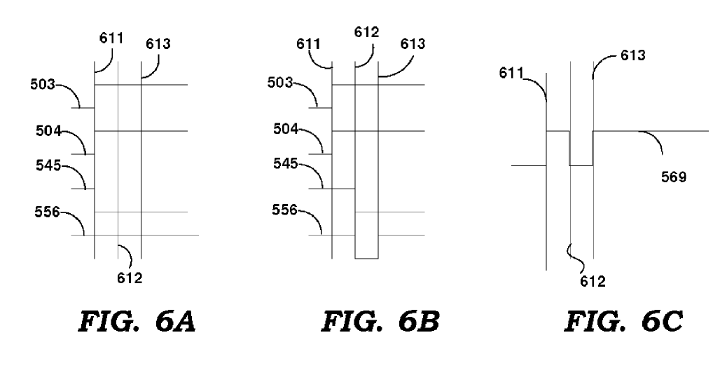

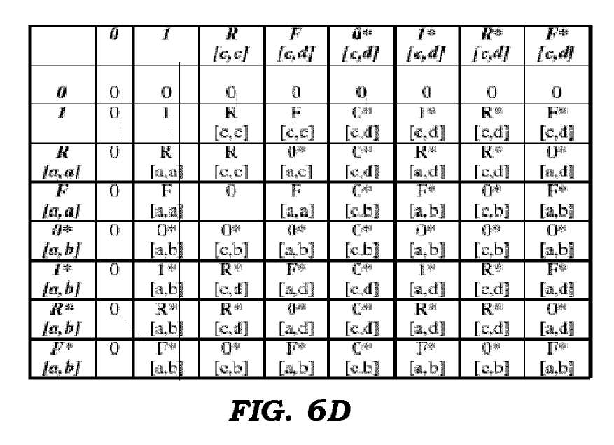

However, other factors causing toggles at the outputs of the logic gates may also be considered in determining the suitable paths to excite a desired value at the fault node (in selecting appropriate input scan vectors). In an embodiment, a path which would be more likely to have more glitches (transients prior to steady state) is considered correspondingly unsuitable since transients also consume power. Accordingly, input scan vectors are selected to avoid exciting such unsuitable paths. Accordingly, the reason for such glitches is described first below with respect to FIGS. 5, and 6A-6C.

### 6. Glitches

FIG. 5 is a circuit diagram illustrating example reasons/sources of glitches (transitions in transient state caused due to different arrival times of inputs), which cause additional power dissipation. For conciseness, possible source of glitch on only the output of NAND gate 550 is illustrated. NAND gate 550 is shown receiving signal 503 on one of the input terminals and inverted signal 545 on the other terminal. Inverted signal 545 is obtained by inverting input signal 504 using inverter 540. The manner in which gate delay may cause a glitch is illustrated with reference to the timing diagrams of FIGS. 6A and 6B.

FIG. 6A illustrates the transition of the signals 545 and 556 in response to input signals 503 and 504 assuming a zero delay of the gates. Input signals 503 and 504 are shown transition from a logic low to logic high. Due to zero delay offered by the gate, the response on path 545 and 556 is shown to occur at same time point 613. Accordingly the output of the NAND gate 550 is maintained at logic high before and after time point 613.

FIG. 6B illustrates the transition of the signals 545 and 556 assuming unequal delay in the input paths. Due to the delay caused by inverter 540, signal 545 transitions to 0 from a logic 1 after some time (611-612). As a result, the NAND gate 550 is provided with inputs of 1 and 1 between time points 611 and 612, causing signal 556 to logic low. However, once the steady state of 1 is reached at time point 613, signal 556 is shown reverting to logic high. The signal between time points 612 and 613 represents a glitch. The glitch between time points 612 and 613 may be referred to as a static glitch since the glitch is produced while maintaining the output of the gate at the same logic level. It may be appreciated that the glitch is caused due to the different arrival times of the input signals.

FIG. 6C illustrates a scenario when multiple glitches occur in the same capture cycle, when a glitch from the previous components in the signal path have caused a glitch. Here it is assumed that the glitch between time points 612 and 613 is presented as an input 556 to NAND gate 560, and another glitch is similarly caused and presented on path 536 due to the operation of NAND gate 530 and inverters 510 and 520. The output 569 is accordingly shown with two glitches. The glitch caused while output transition from one logic to other logic is referred to as a dynamic glitch.

It may be appreciated that, the number of glitches may be determined (using circuit simulation etc.,) at an output of the gate based on the nature of the input. In one embodiment of the present invention, number of/magnitude of glitches are stored for each gates in the integrated circuit correspondingly for possible inputs. The number of glitches are added to number of transitions (toggles) to determine the total number of toggles in a portion. The manner in which magnitude of glitch may be stored corresponding to various input values is illustrated with reference to FIG. 6D.

FIG. 6D is an example table depicting the magnitude of the glitches considering a unit delay at the output of an AND gate for each combination of input signals. The table depicts the magnitude of the glitches in terms of signal arrival and departure times (during which output signal stabilizes to desired logical value).

The values in first row represent the possible inputs on one of the input terminal and values in first column represents the inputs on the other terminal. The magnitude and type of glitches for each possible input combination is represented in the box corresponding to the row and column.

0* and 1* respectively represent static glitches while maintaining the logic_{—}0 and logic-1 at the output of AND gate. R* and F* respectively represents a glitch while output rises (from 0 to 1) and falls. The value a, b, c, d are assumed such that a<c<b<d. The value a and b in the square bracket ([a,b]) respectively indicate signal arrival time at the input and signal departure time at the output of AND gate. The magnitude of the glitch is proportional to the difference between the departure time and the arrival time (time taken to stabilize). Letters R and F respectively indicate transitions (i.e., without glitch) due to rise and Fall at the output.

In one embodiment of the present invention, two toggles are attributed to every static glitch and three toggles are attributed to every dynamic glitch. However, different number of transitions may be attributed based on other parameters or by simulating the circuit and computing the glitches.

It should be appreciated that glitches such as those described above can be caused due to other reasons as well. For example, even if gates have zero delays, the input signals (or transitions) can arrive at different times due to propagation delay in a path.

In general, the paths which are likely to have glitches can be determined by estimating the signal arrival times, which would in turn depend on the expected delays that would be caused by each logical component and path segments. Such delay information is often available from various design tools given the fabrication technology and circuit specification (including the layout information). Determination of possibility of such glitches (based on the delay information) will be apparent to one skilled in the relevant arts at least by reading the disclosure provided herein.

The manner in which the thresholds of FIG. 3 (or in particular 4B) are used in conjunction with the information on paths with potential glitches in generating input scan vectors, is described below with examples.

### 7. Determination of Scan Vector

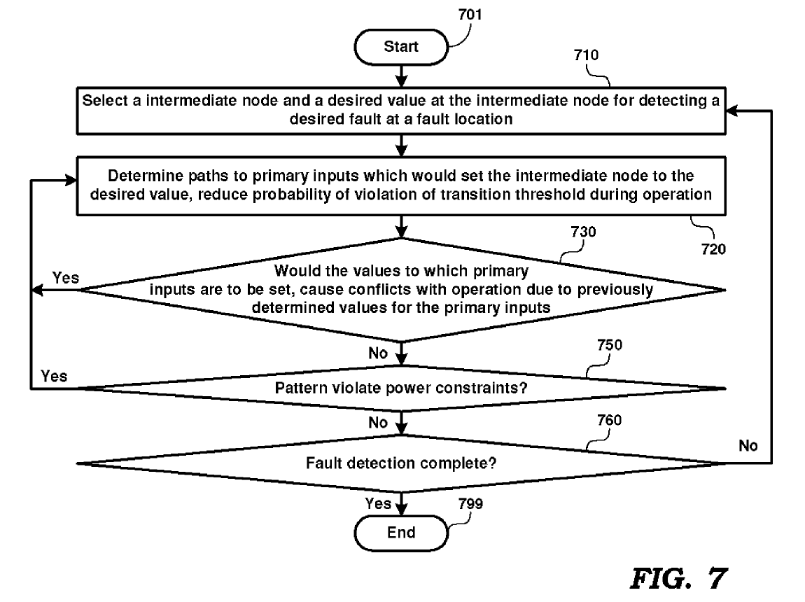

FIG. 7 is a flowchart illustrating the manner in which an input scan vector can be determined for testing a fault location according to an aspect of present invention. The flow chart is illustrated with reference to FIGS. 1 and 2 merely for illustration. However the features can be implemented in other environments as will be apparent to one skilled in the relevant arts by reading the disclosure provided herein, and many of such implementations are covered by at least some aspects of the present invention. The flow chart begins in step 701 and control passes to step 710.

In step 710, ATPG 140 selects an intermediate node and a desired value at the intermediate node for detecting a desired fault at the fault location. Intermediate node and the corresponding values are set to excite a fault location to a desired value and/or to propagate the fault (for example D (detect) signal as is commonly referred to in the relevant art) signal to an flip-flop on the scan-out chain (say 290B).

In step 720, ATPG 140 determines paths to primary inputs which would set the intermediate node to the desired value, reduce probability of violation of transition threshold (in the portions of integrated circuit) during operation. Reduction of probabilities generally entails choosing paths which contribute a correspondingly lower number to the corresponding aggregate count.

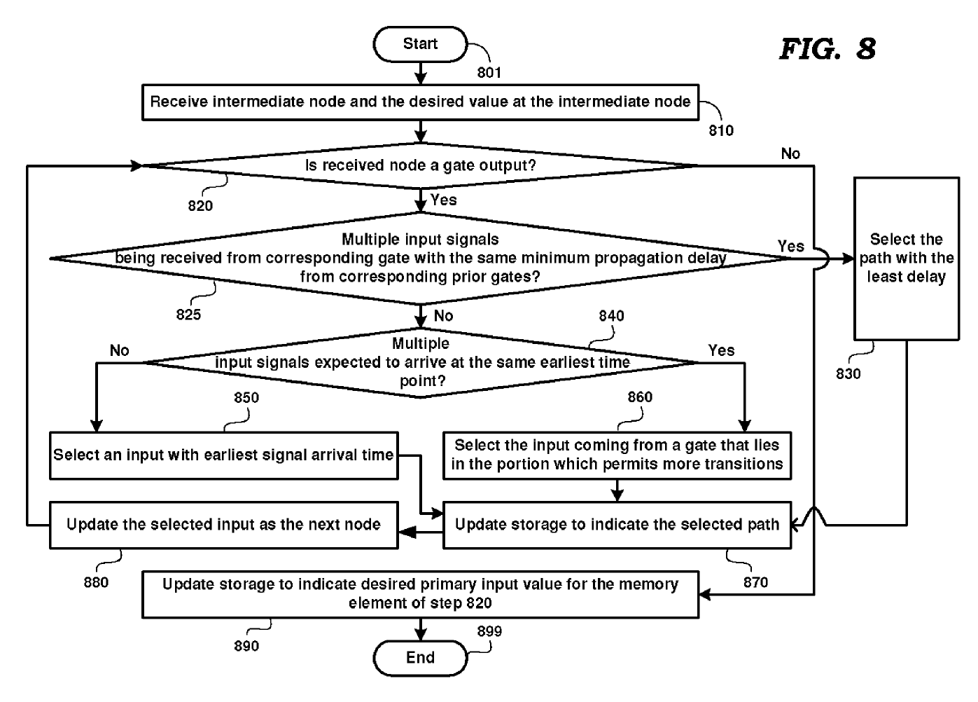

In general, the paths which are likely to have glitches can be determined by estimating the signal arrival times, which would in turn depend on the expected delays that would be caused by each logical component and path segments. Accordingly, an example approach for selecting a path that contribute relatively lower number of transitions (lesser glitch) is described with reference to FIG. 8 below in further detail.

In step 730, ATPG 140 checks if the values to which primary inputs are to be set, would cause conflicts with operation due to previously determined values for the primary inputs. If a conflict is identified, the control passes to step 720, else to step 750. In one embodiment, the check is performed by simulating the network and calculating the effect (implication of) of fixing the primary input at the value determined in step 720. A conflict is deemed to be present if the value do not set the desired node at the desired value or if the propagation of fault (to the scan chain) is not possible.

In step 750, ATPG 140 checks if the generated pattern violates power constraints/thresholds. The number of toggles corresponding to the input pattern may be computed using any of the known technique. The number of transition due to glitches may be obtained from table in FIG. 6D. The aggregate number of toggle is compared with the thresholds of FIG. 4B in the corresponding region. If the determined number of toggles exceeds the thresholds in the corresponding portion or the total number of toggle exceeds the global limit, control passes to step 720, else to 760.

In step 760, ATPG 140 checks if fault detection is complete. Fault detection may be complete when all the nodes (inputs and outputs of gates in the IC sought to be tested) in the network are assigned with a value and the fault/detect signals (D signal) would propagate to an output nodes (a flip-flop input) during testing. If the fault detection is complete, control passes to step 799, else to step 710. The flowchart ends in step 799.

The manner in which step 720 is performed in one embodiment of the present invention is described below in further detail below.

### 8. Path Selection

FIG. 8 is a flowchart illustrating the determination of paths according an aspect of present invention. The flowchart is illustrated with reference to FIGS. 1, 7 and 9 (which is a circuit contained in IC 180 of FIG. 1, and is shown containing NAND gates 910A-910P, 920 and 940) merely for illustration. However the features can be implemented in other environments as will be apparent to one skilled in the relevant arts by reading the disclosure provided herein, and such implementations are covered by at least some aspects of the present invention. The flow chart begins in step 801 and control passes to step 810.

In step 810, ATPG 140 receives intermediate node and the desired value at the intermediate node. For illustration, it is assumed that path/node 924 to be the intermediate node and the desired value on path 949 is logic 1.

In step 820, ATPG 140 checks if the received node is a gate output, i.e., the primary input is not reached (since the primary inputs would be provided by a flip-flop). Control passes to step 825 if so, and to step 890 otherwise. Thus, in the first iteration, the intermediate node (924) represents the received node and control would pass to step 825.

In step 825, ATPG 140 checks if multiple input signals are being received from corresponding gate with the same minimum propagation delay from corresponding prior gates. For example, when 924 is the present node, it is checked to determine if at least two of the input signals 912A-912P have same minimum propagation delay.

Control passes to step 830 if there is only one input signal with minimum propagation delay and to step 840 otherwise. In step 830, ATPG 140 selects the path/node with the least delay as being the desired path to the primary input. Control then passes to step 870, in which ATPG 140 updates storage to indicate the selected path. Control then passes to step 880.

In step 840, ATPG 140 checks if multiple input signals are expected to arrive at the same earliest time point. In general, the delays from the primary inputs along with path are added to compute the expected arrival time, and can be determined using various static timing analysis techniques well known in the relevant arts.

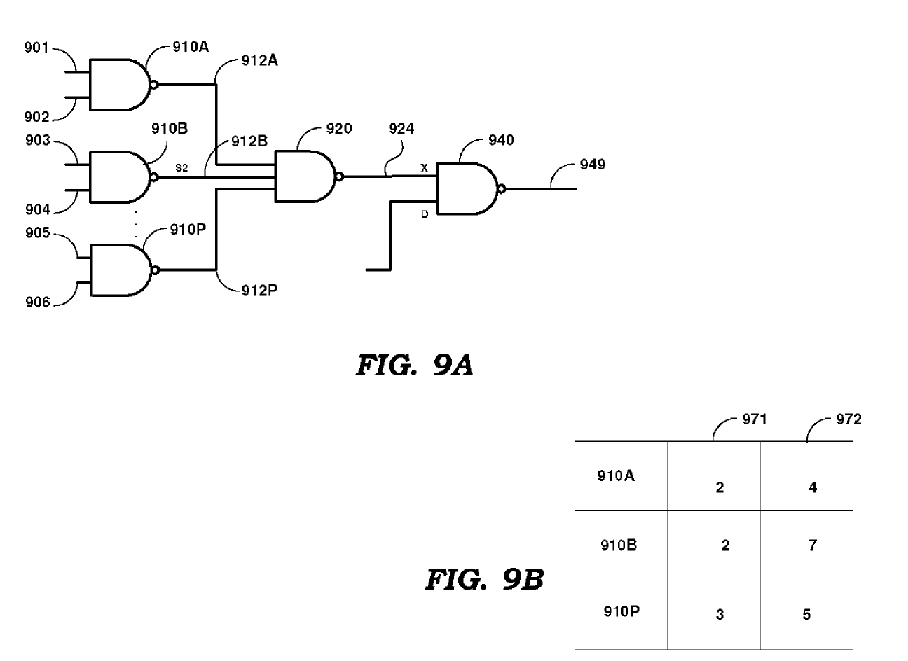

Such information is shown represented in FIG. 9B which indicates the signal arrival time 971 (time taken from primary input to arrive at the gate input) and signal leaving time 972 (when a stable response would be expected to be seen on a gate output after being received at the input) for gates 910A,910B and 910P. Control passes to step 860 if there is more than one of such input signals, and to step 850 otherwise.

In step 850, ATPG 140 selects an input signal with earliest signal arrival time. As may be appreciated, the combination of steps 830, 840 and 850 operate to reduce the probability of glitches on the selected path. Control then transfers to step 870, described above.

As an illustration, assuming the selected node is 924, since node 924 is an output of NAND gate 920, according to step 825, ATPG 140 selects the inputs 912A-912P coming from gate having minimum delay (timing window) of 2 (In FIG. 9B, the difference between 971 and 972 represents delay). Since multiple input terminals having minimum timing window are found, ATPG selects path 912A which is the output of NAND gate 910A having earliest signal arrival time (2). The NAND gate 910A is stored into storage (e.g., in the form of a stack data structure) as being selected. Path 912A is set as intermediate node and the processing is continued with respect to step 870.

In step 860, ATPG 140 selects the input coming from a gate that lies in the portion which permits more transitions. For example, paths in grids having high strap thickness may be chosen such that the potential glitches are more tolerable in such areas. Other considerations such as the number of paths already selected in the portion and the number of transitions that would be caused by such paths, may also be considered in selecting the input. Control then passes to step 870.

In step 880, ATPG 140 updates the selected input as the next received node and control passes to step 820.

In step 890, ATPG 140 updates the storage to indicate desired primary input value for the memory element of step 820. This indicates that the desired path to the primary input (from desired node, which is the fault location in case of a first iteration of FIG. 7) is obtained. The corresponding information is then provided to step 730 for validation. The flowchart ends in step 899.

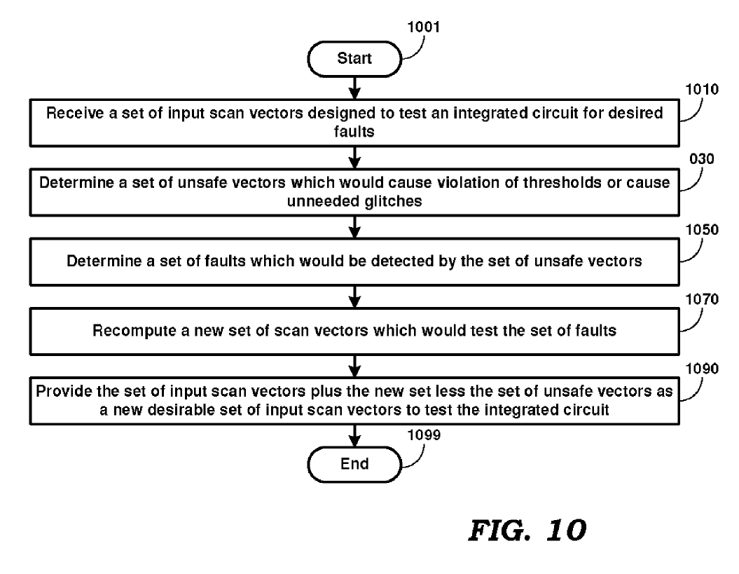

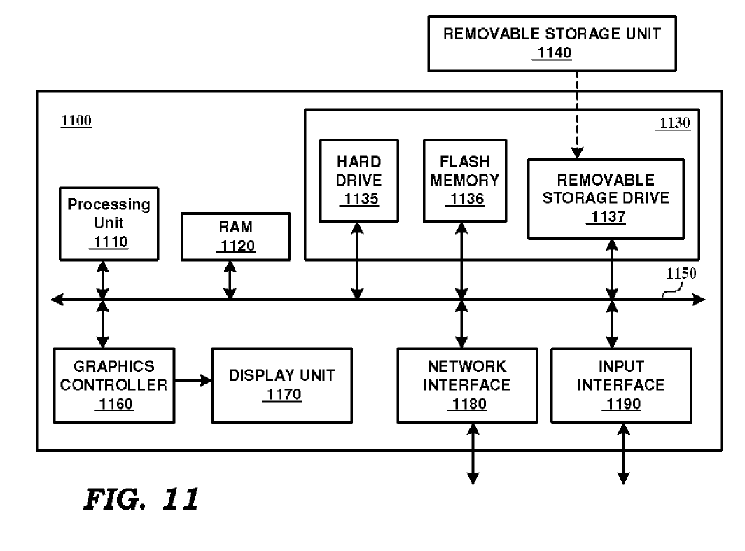

Due to above approach, the patterns that reduce probability of violation of transition threshold are generated by selecting a path contributing lesser glitch. The pattern generation technique described above may be used to provide an optimized set of input scan vectors from an existing set of scan vectors. Accordingly, such a feature is described below with reference to FIG. 10.

### 9. Pattern Optimization

FIG. 10 is a flowchart illustrating the manner in which an optimized set of input scan vectors may be generated from an initial pattern set containing many vectors. The flow chart is illustrated with respect to FIGS. 1, 7, and 8. The flowchart begins in step 1001 and control passes to step 1010.

In step 1010, ATPG 140 receives a set of input scan vectors designed to test an integrated circuit for desired faults. An existing set of vectors generated using any of the known techniques may be provided as input to the ATPG 140.

In step 1030, ATPG 140 determines a set of unsafe vectors which would cause violation of thresholds or cause unneeded glitches. For each vector, in the database, a simulation is performed and a number of transitions and glitches are computed using FIG. 6D. The vectors may be classified into safe and non-safe vectors according to the aggregate number of toggles, for example, if a vector does not cause a total number of toggles exceeding corresponding threshold.

In step 1050, ATPG 140 determines a set of faults which would be detected by the set of unsafe vectors. For each unsafe vector, the fault that were intended to be detected are determined. Determination of fault coverage by a vector is performed using known techniques. Often such information is provided in the database.

In step 1070, ATPG 140 recomputes a new set of scan vectors which would test the set of faults. The fault information is used to generate a new set of power safe vectors as described with reference to FIGS. 7 and 8.

In step 1090, ATPG 140 provides the set of input scan vectors plus the new set less the set of unsafe vectors as a new desirable set of input scan vectors to test the integrated circuit. The unsafe vectors are removed from the database and the new set of vectors computed in step 1070 are added to the database. Such an approach optimizes processing power without re-computing the power safe vectors that are already available in the database. The flow chart ends in step 1099.

It should be appreciated that the features described above can be implemented in a combination of one or more of hardware, software and firmware. The description is continued with respect to an embodiment in which the features are operative by execution of software instructions as described below in further detail.

### 10. Digital Processing System

FIG. 1 is a block diagram of digital processing system 1100 illustrating an example system in which various aspects of the present invention can be implement. System 1100 may correspond to tester (ATPG/ATVG) 140 or a design tool (computer aided design tool) using which test pasterns may be generated. Computer system 1100 may contain one or more processors such as central processing unit (CPU) 1110, random access memory (RAM) 1120, secondary memory 1130, graphics controllers 1160, display unit 1170, network interface 1180, and input interface 1190. All the components except display unit 1170 may communicate with each other over communication path 1150, which may contain several buses as is well known in the relevant arts. The components of FIG. 1 are described below in further detail.

CPU 1110 may execute instructions stored in RAM 1120 to provide several features of the present invention. For example, the CAD tool may examine the digital representation (e.g., Netlists, well known in the relevant arts) to perform various steps of FIG. 3, provide for computing the test patterns as described above. On the other hand, ATE 160 may generate the various signals to cause operation of some of the steps of FIG. 4, described above.

CPU 1110 may contain multiple processing units, with each processing unit potentially being designed for a specific task. Alternatively, CPU 1110 may contain only a single processing unit. RAM 1120 may receive instructions from secondary memory 1130 using communication path 1150.

Graphics controller 1160 generates display signals (e.g., in RGB format) to display unit 1170 based on data/instructions received from CPU 1110. Display unit 1170 contains a display screen to display the images defined by the display signals. Input interface 1190 may correspond to a key_board and/or mouse, and generally enables a user to provide inputs. Network interface 1180 enables some of the inputs (and outputs) to be provided on a network. In general, display unit 1170, input interface 1190 and network interface 1180 enable a user to design an integrated circuit.

Secondary memory 1130 may contain hard drive 1131, flash memory 1136 and removable storage drive 1137. Secondary storage 1130 may store the software instructions (which perform the actions specified by various flow charts above) and data (e.g., netlists of the integrated circuits), which enable computer system 1100 to provide several features in accordance with the present invention.

Some or all of the data and instructions may be provided on removable storage unit 1140, and the data and instructions may be read and provided by removable storage drive 1137 to CPU 1110. Floppy drive, magnetic tape drive, CD_ROM drive, DVD Drive, Flash memory, removable memory chip (PCMCIA Card, EPROM) are examples of such removable storage drive 1137.

Removable storage unit 1140 may be implemented using medium and storage format compatible with removable storage drive 1137 such that removable storage drive 1137 can read the data and instructions. Thus, removable storage unit 1140 includes a computer readable storage medium having stored therein computer software and/or data. An embodiment of the present invention is implemented using software running (that is, executing) in computer system 1100.

In this document, the term “computer program product” is used to generally refer to removable storage unit 1140 or hard disk installed in hard drive 1131. These computer program products are means for providing software to computer system 1100. As noted above, CPU 1110 may retrieve the software instructions, and execute the instructions to provide various features of the present invention.

### 11. Conclusion

While various embodiments of the present invention have been described above, it should be understood that they have been presented by way of example only, and not limitation. Thus, the breadth and scope of the present invention should not be limited by any of the above described exemplary embodiments, but should be defined only in accordance with the following claims and their equivalents.

What is claimed is:

1. A method of generating test vectors for an integrated circuit (IC) containing a plurality of sequential elements connected by a plurality of combinatorial elements, wherein said plurality of combinatorial elements are laid in a plurality of portions of a physical layout of said IC, said method comprising:
receiving a circuit description of said integrated circuit and a plurality of thresholds, said circuit description including an indication of in which of said plurality of portions each of said plurality of combinatorial elements is physically located, wherein each of said plurality of thresholds is associated with the corresponding one of said plurality of portions; and
determining a scan vector such that said scan vector would test a desired set of fault locations without exceeding said plurality of thresholds in corresponding portions of said physical layout during testing of said integrated circuit.

2. The method of claim 1, wherein each of said plurality of thresholds indicates a corresponding aggregate toggle counts at the outputs of combinatorial elements laid in the corresponding portion.

3. The method of claim 2, wherein said aggregate toggle count includes count of transitions due to logical operation of said plurality of combinatorial elements.

4. The method of claim 3, wherein said aggregate toggle count includes glitches caused due to input signals of gates arriving at different time points.

5. The method of claim 4, wherein said plurality of thresholds is determined by the power dissipation ability in the corresponding portions of said integrated circuit.

6. The method of claim 5, wherein said plurality of threshold is higher for a portion having thicker grid straps compared to portions having thinner grid straps.

7. The method of claim 4, further comprising:
storing an expected time of arrival of each input signal and an expected time of departure of the output signal for each of the combinatorial elements;
determining a number of glitches for each combinatorial element in a capture cycle based on said expected time of arrival and said expected time of departure.

8. The method of claim 4, further comprising:
storing a second data representing whether rise without glitch, fall without glitch, static 0, static 1, rise with glitch, or fall with glitch would be caused as an expected state at the output of a combinatorial element by each combination of rise without glitch, fall without glitch, static 0, static 1, rise with glitch, fall with glitch of the inputs of said combinatorial element,
wherein a glitch count is attributed to each of said combinatorial element based on said second data.

9. The method of claim 8, wherein a respective pre-specified value is attributed for each corresponding expected state at the output.

10. A method of generating test vectors for an integrated circuit (IC) containing a plurality of sequential elements connected by a plurality of combinatorial elements, wherein said plurality of combinatorial elements are laid in a plurality of portions of a physical layout of said IC, said method comprising:
receiving a circuit description of said integrated circuit and data indicating a corresponding delay caused by a set of combinatorial elements;
determining a plurality of glitches at the output of said set of combinatorial elements caused due to said corresponding delays; and
considering said plurality of glitches in generating a test vector in testing said IC.

11. A method of generating test vectors for an integrated circuit (IC) containing a plurality of sequential elements connected by a plurality of combinatorial elements, said method comprising:
receiving an intermediate node in a combinatorial logic and a desired value to be set at said intermediate node, wherein said intermediate node corresponds to the output of a first combinatorial element;
finding a plurality of paths from said first combinatorial element, wherein each of said plurality of paths connects an input path of said first combinatorial element to the output path of one of said plurality of sequential elements; and
selecting one of said plurality of paths as a path to be excited for setting said intermediate node to said desired value based on at least one of a timing and a physical characteristic of components in the paths.

12. The method of claim 11, wherein said plurality of combinatorial elements are laid in a plurality of portions of a physical layout of said IC, wherein said characteristic comprises one of a delay introduced by a combinatorial element in the path, an expected signal arrival time and the specific ones of said plurality of portions in which the combinatorial elements in the path are located, wherein said physical location is the location on a die on which said integrated circuit is intended to be fabricated.

13. The method of claim 11, wherein said components comprise combinatorial elements and signal paths connecting said combinatorial elements and said plurality of sequential elements.

14. A method of generating test vectors for an integrated circuit (IC) containing a plurality of sequential elements connected by a plurality of combinatorial elements, said method comprising:
receiving an intermediate node in a combinatorial logic, wherein said intermediate node corresponds to the output of a first combinatorial element;
finding a second combinatorial element that drives a first input of said first combinatorial element, and a third combinatorial element that drives a second input of said first combinatorial element;
checking whether a delay offered by said second combinatorial element is less than a delay offered by said third combinatorial element; and
including said second combinatorial element or said third combinatorial element in a path, wherein said path connects said intermediate node to one of a plurality of primary inputs, wherein a primary input is an output terminal of one of said plurality of sequential elements.

15. The method of claim 14, wherein said including includes said second combinatorial element in said path if said checking indicates that the delay offered by said second combinatorial element is less than the delay offered by said third combinatorial element.

16. The method of claim 15, wherein said checking indicates that the delay offered by said second combinatorial element equals the delay offered by said third combinatorial element, wherein said checking further checks whether an expected time of arrival of signal to said second combinatorial element is sooner than an expected time of arrival of signal to said third combinatorial element, wherein said including includes said second combinatorial element or said third combinatorial element in said path based on the result of said checking of said expected time of arrival.

17. The method of claim 16, wherein said including includes said second combinatorial element in said path if the expected time of arrival signal to said second combinatorial element is determined to be sooner than the expected time of arrival signal to said third combinatorial element.

18. The method of claim 17, wherein said plurality of combinatorial elements are laid in a plurality of portions of a physical layout of said IC, wherein each of said plurality of portions is associated with a corresponding threshold representing a number of toggles permitted in a unit time, wherein said checking indicates that the expected arrival time of respective signal is same, wherein said including includes one of said second combinatorial element and said third combinatorial element to minimize a probability that said thresholds are not exceeded.

19. The method of claim 18, wherein said second combinatorial element is contained in a second portion having a second threshold, and said third combinatorial element is contained in a third portion having a third threshold, wherein said second threshold is greater than said third threshold, wherein said including includes said second combinatorial element in said path.

20. A method of generating a set of acceptable scan vectors from a set of initial scan vectors to test an integrated circuit for a desired set of faults, wherein said integrated circuit is divided into a plurality of portions, said integrated circuit containing a plurality of combinatorial elements connecting a plurality of sequential elements, said method comprising:
receiving a plurality of threshold values, wherein each threshold value is associated with a corresponding portion;
determining a set of unsafe vectors contained in said set of initial scan vectors which cause violation of threshold in said corresponding portion when said integrated circuit is tested with each of said set of unsafe vectors;
determining a subset of faults which are detected by said set of unsafe vectors;
computing a set of replacement vectors which would test said subset of faults; and
forming said set of acceptable scan vectors by replacing said set of unsafe vectors with said set of replacement vectors in said set of initial scan vectors.

21. The method of claim 20, wherein each of said plurality of threshold values represents a number of toggles permitted in said corresponding portion.

22. The method of claim 21, wherein said number of toggles represents both a number of transitions and a number of glitches.

23. A computer readable medium carrying one or more sequences of instructions to cause a digital processing system to generate test vectors for testing an integrated circuit (IC) containing a plurality of sequential elements connected by a plurality of combinatorial elements using a digital processing system, wherein said plurality of combinatorial elements are laid in a plurality of portions of a physical layout of said IC, wherein execution of said one or more sequences of instructions by one or more processors contained in said digital processing system causes said one or more processors to perform the actions of:
receiving a circuit description of said integrated circuit and a plurality of thresholds, said circuit description including an indication of in which of said plurality of portions each of said plurality of combinatorial elements is physically located, wherein each of said plurality of thresholds is associated with the corresponding one of said plurality of portions; and
determining a scan vector such that said scan vector would test a desired set of fault locations without exceeding said plurality of thresholds in corresponding portions of said physical layout during testing of said integrated circuit.

24. A computer readable medium carrying one or more sequences of instructions to cause a digital processing system to generate test vectors for testing an integrated circuit (IC) containing a plurality of sequential elements connected by a plurality of combinatorial elements using a digital processing system, wherein said plurality of combinatorial elements are laid in a plurality of portions of a physical layout of said IC, wherein execution of said one or more sequences of instructions by one or more processors contained in said digital processing system causes said one or more processors to perform the actions of:
receiving a circuit description of said integrated circuit and data indicating a corresponding delay caused by a set of combinatorial elements;
determining a plurality of glitches at the output of said set of combinatorial elements caused due to said corresponding delays; and
considering said plurality of glitches in generating a test vector in testing said IC.
